(19) United States
(12) Patent Application Publication
(10) Pub. No.: US 2019/0172775 A1
(43) Pub. Date: Jun. 6, 2019

(54) FLEXIBLE SUBSTRATE AND ELECTRONIC DEVICE

(71) Applicant: CANON COMPONENTS, INC., Kodama-gun (JP)

(72) Inventor: Akihiro SAKATA, Kodama-gun (JP)

(21) Appl. No.: 16/205,790

(22) Filed: Nov. 30, 2018

(30) Foreign Application Priority Data
Dec. 4, 2017 (JP) 2017-232719
Nov. 29, 2018 (JP) 2018-223936

(51) Int. Cl. H01L 23/498; H01L 23/00; H01L 21/48

(52) U.S. Cl. CPC H01L 23/4985; H01L 23/49822; H01L 23/49838; H01L 23/49894; H01L 2224/16227; H01L 21/4857; H01L 21/486; H01L 24/16; H01L 23/562

(57) ABSTRACT

A flexible substrate according to the present invention comprises a first resin layer, a first wiring layer that is arranged on the first resin layer, a second resin layer that is arranged on the first resin layer so as to cover the first wiring layer, and a second wiring layer that is arranged on the second resin layer, wherein the first wiring layer and the second wiring layer are connected to each other with a filled via, and the first wiring layer and the second resin layer are in direct contact with each other. By virtue of this feature, the reliability of a flexible substrate will be improved with a relatively simple configuration.

### BACKGROUND OF THE INVENTION

### Field of the Invention

The present invention relates to a flexible substrate and an electronic device.

### Description of the Related Art

Some electronic devices include a plurality of electronic components and a flexible substrate for connecting the electronic components, and as a result of such a configuration, electrical communication is possible between the electronic components. The flexible substrate includes a base material made of a flexible resin such as polyimide, for example, and a wiring structure formed by a wiring layer, vias, and the like, and can be formed to have a layered structure in which some layers are stacked (refer to Japanese Patent Laid-Open No. 2007-204696).

In many cases, a flexible substrate is bent due to its flexibility when being attached to an electronic device, and after attachment as well, the flexible substrate is fixed in the electronic device in a bent state. It is possible that, in such a process, exfoliation or the like occurs in any of the layers that constitute the flexible substrate. It is also possible that, when the electronic device is used, exfoliation or the like similarly occurs due to thermal expansion of the layers in accordance with the change in temperature. These phenomena may cause degradation in the reliability of the flexible substrate, and in particular, may be a serious problem when the density or the complexity of the wiring structure of the flexible substrate increases in accordance with a substantial increase in the number of terminals of individual electronic components.

The present invention aims to improve the reliability of a flexible substrate with a relatively simple configuration.

### SUMMARY OF THE INVENTION

One aspect of the present invention relates to a flexible substrate, and the flexible substrate comprises a first resin layer, a first wiring layer that is arranged on the first resin layer, a second resin layer that is arranged on the first resin layer so as to cover the first wiring layer, and a second wiring layer that is arranged on the second resin layer, wherein the first wiring layer and the second wiring layer are connected to each other with a filled via, and the first wiring layer and the second resin layer are in direct contact with each other.

Further features of the present invention will become apparent from the following description of exemplary embodiments (with reference to the attached drawings).

### BRIEF DESCRIPTION OF THE DRAWINGS

FIG. 1A is a cross-sectional view for describing a reference example of the structure and the manufacturing method of a flexible substrate.

FIG. 1B is a cross-sectional view for describing the reference example of the structure and the manufacturing method of a flexible substrate.

FIG. 1C is a cross-sectional view for describing the reference example of the structure and the manufacturing method of a flexible substrate.

FIG. 1D is a cross-sectional view for describing the reference example of the structure and the manufacturing method of a flexible substrate.

FIG. 1E is a cross-sectional view for describing the reference example of the structure and the manufacturing method of a flexible substrate.

FIG. 2A is a cross-sectional view for describing an example of the structure and the manufacturing method of a flexible substrate according to an embodiment.

FIG. 2B is a cross-sectional view for describing the example of the structure and the manufacturing method of the flexible substrate according to the embodiment.

FIG. 2C is a cross-sectional view for describing the example of the structure and the manufacturing method of the flexible substrate according to the embodiment.

FIG. 2D is a cross-sectional view for describing the example of the structure and the manufacturing method of the flexible substrate according to the embodiment.

FIG. 3A is a cross-sectional view for describing various modifications of the structure of the flexible substrate according to the embodiment.

FIG. 3B is a cross-sectional view for describing various modifications of the structure of the flexible substrate according to the embodiment.

FIG. 4 is a cross-sectional view for describing an example of the mode of mounting electronic components on the flexible substrate according to the embodiment.

FIG. 5A is a cross-sectional view for describing an example of the structure and the manufacturing method of the flexible substrate according to an embodiment.

FIG. 5B is a cross-sectional view for describing the example of the structure and the manufacturing method of the flexible substrate according to the embodiment.

FIG. 5C is a cross-sectional view for describing the example of the structure and the manufacturing method of the flexible substrate according to the embodiment.

FIG. 5D is a cross-sectional view for describing the example of the structure and the manufacturing method of the flexible substrate according to the embodiment.

FIG. 5E is a cross-sectional view for describing the example of the structure and the manufacturing method of the flexible substrate according to the embodiment.

FIG. 6A is a cross-sectional view for describing an example of the structure and the manufacturing method of the flexible substrate according to an embodiment.

FIG. 6B is a cross-sectional view for describing the example of the structure and the manufacturing method of the flexible substrate according to the embodiment.

### DESCRIPTION OF THE EMBODIMENTS

Hereinafter, suitable embodiments of the present invention will be described with reference to the attached drawings. Note that the drawings are merely schematic diagrams that are described for the purpose of describing structures or configurations, and the sizes of members shown in the drawings may be different from those of actual members. Also, in the drawings, the same members or the same constituent elements are given the same reference numbers, and redundant descriptions will be omitted.

### Reference Example

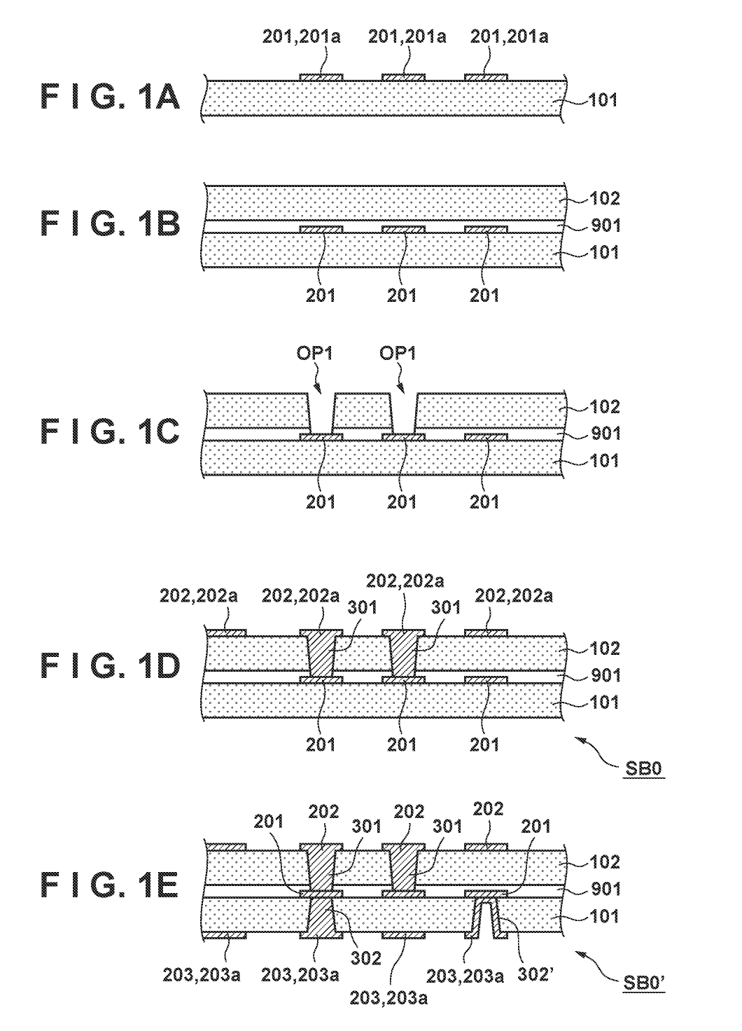

For the purpose of facilitating understanding of the present invention, first, a reference example of the flexible substrate and the manufacturing method thereof will be described. FIGS. 1A to 1E are cross-sectional views that show modes of respective processes in the manufacturing method of the reference example.

In the process in FIG. 1A, a first wiring layer 201 is formed on a first resin layer 101. The resin layer 101 is a member that serves as a base material or a parent material of the flexible substrate, and polyimide is used as the resin layer 101 in this reference example, but another flexible resin may be used. The wiring layer 201 includes a plurality of wiring patterns (alternatively, expressed as line patterns) 201a, in a cross-sectional view (when a cross section in a vertical direction is viewed). The plurality of wiring patterns 201a can be provided side by side at intervals of about 10 to 100 [μm].

The plurality of wiring patterns 201a show a mode in which two or more conductive members are present in a predetermined cross section, and the conductive members need not be electrically isolated. When the plurality of wiring patterns 201a are not specifically distinguished, these are collectively referred to as simply a “wiring layer 201” in order to simplify the description in this specification. This similarly applies to other later-described wiring layers.

Note that, in this specification, the expressions such as upper/lower are used to indicate a relative positional relationship, and here, upper/lower are indicated based on the positional relationship in a vertical direction in the drawings (a direction vertical to the surface direction of the resin layer 101). Also, the direction orthogonal to the vertical direction corresponds to a horizontal direction (surface direction).

In the process shown in FIG. 1B, a second resin layer 102 is formed on a structure obtained in the process shown in FIG. 1A via an adhesion layer 901. The resin layer 102 is a member serving as a base material or a parent material of the flexible substrate, similarly to the resin layer 101, and polyimide is used as the resin layer 102 in this reference example. Note that a known adhesive such as an epoxy-based resin may be used as the adhesion layer 901.

In the process shown in FIG. 1C, etching is performed from above on the structure obtained in the process shown in FIG. 1B, and openings OP1 are formed such that desired portions of the upper surface of the wiring layer 201 are exposed. This process may be performed using a known laser such as a UV laser or a CO2 laser.

In the process shown in FIG. 1D, a second wiring layer 202 including a plurality of wiring patterns 202a is formed on the resin layer 102, and also first vias 301 for connecting the wiring layers 201 and 202 are formed. This process can be realized by performing film forming processing using an electroless plating method or an electroplating method and patterning processing using the photoresist technology. Copper is used in the wiring layer 202 and the vias 301 in this reference example. The structure obtained in this way is a flexible substrate SB0.

In the example described above, two wiring layers (wiring layers 201 and 202) are used, but, as shown in FIG. 1E, a third wiring layer 203 and second vias 302 and 302′ may be further formed, in addition, on a lower side of the flexible substrate SB0. This structure is a flexible substrate SB0′. The wiring layer 203 includes a plurality of wiring patterns 203a, and is formed under the resin layer 101. The vias 302 and 302′ are formed so as to connect the wiring layers 201 and 203. Copper is used in the wiring layer 203 and the vias 302 and 302′, similarly to the wiring layer 202 and vias 301.

The above-described flexible substrate SB0′ can be realized by forming other openings in the resin layer 101 when the openings OP1 are formed in the process shown in FIG. 1C, and forming the wiring layer 203 and the vias 302 and 302′ when the wiring layer 202 and the vias 301 are formed in the process shown in FIG. 1D. Alternatively, the flexible substrate SB0′ can be realized by further performing etching, film forming processing, and patterning processing on the lower side of the flexible substrate SB0 obtained in the process shown in FIG. 1D using procedures similar to the processes shown in FIGS. 1C and 1D.

The via 302 is formed by approximately completely filling the opening provided in the resin layer 101 such that an upper face thereof is flat, and is referred to as a filled via. Also, the via 302′ is formed by partially filling the other opening provided in the resin layer 101 such that an upper face thereof has a recessed shape, and is referred to as a conformal via. Any of the vias 302 and 302′ may be formed as a member for connecting the wiring layers 201 and 203. Note that, here, the wiring layer 203 and the via 302 (or 302′) are integrally provided, the wiring layer 203 corresponds to a portion that extends in a direction parallel to the direction in which the resin layer 101 extends, and the via 302 (or 302′) corresponds to a portion that extends in a direction orthogonal to the direction in which the resin layer 101 extends.

The manufacturing method of the above-described reference example can be realized using a known manufacturing technology. Predetermined electronic components are mounted, thereafter, on the flexible substrate SB0 and/or flexible substrate SB0′ obtained in this way, and the flexible substrate SB0 and/or flexible substrate SB0′ are/is attached to an electronic device.

### First Embodiment

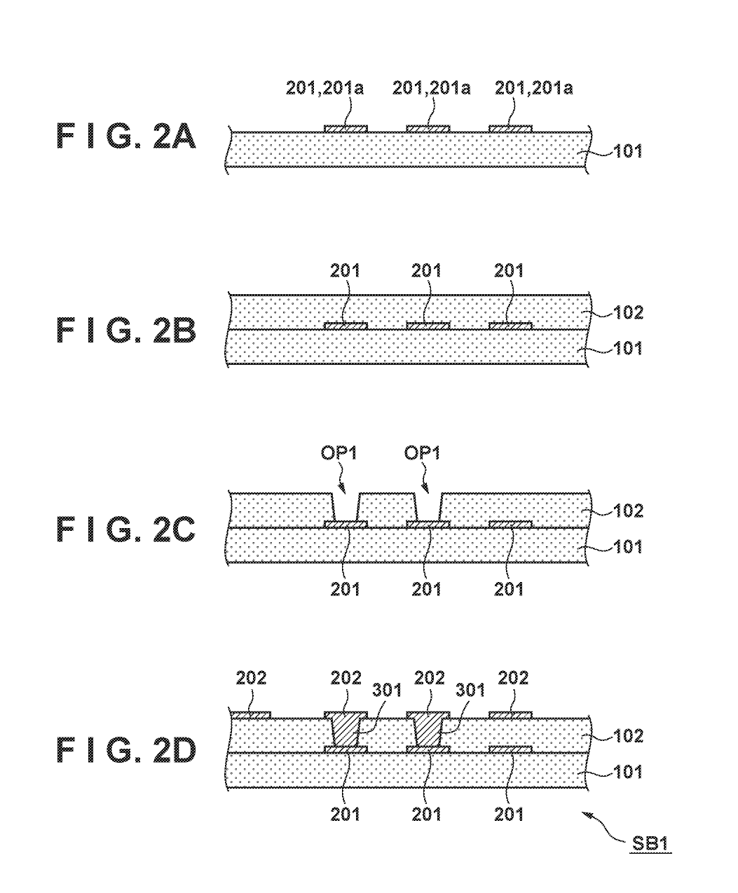

Hereinafter, a flexible substrate according to a first embodiment and its manufacturing method will be described. The manufacturing method according to the present embodiment can be realized using a known manufacturing technology, similarly to the reference example. In the following, processes and constituents elements that are the same as those in the reference example will not be described, and descriptions thereof are the same as those given in the reference example. FIGS. 2A to 2D are cross-sectional views that show modes of respective processes in the manufacturing method according to the present embodiment.

After a wiring layer 201 is formed on a resin layer 101 in the process shown in FIG. 2A (similarly to FIG. 1A), a resin layer 102 is integrally formed on the resin layer 101 so as to cover the wiring layer 201, in the process shown in FIG. 2B. In this process, the resin layer 102 is in a B stage (semi-cured state), and can be deformed, and therefore, the resin layer 102 is formed so as to fill portions between adjacent wiring patterns (hereinafter referred to as “adjacent patterns”) 201a in the wiring layer 201, as shown in the diagram. Therefore, the wiring layer 201 is in direct contact with the resin layer 102. Also, in the present embodiment, the resin layer 102 is directly formed on the resin layer 101 without an adhesion layer 901 being interposed therebetween. The resin layer 102 may be formed using a known thermocompression bonding apparatus.

In the process shown in FIG. 2C, the resin layer 102 in a B stage is cured (so as to be in a C stage) by performing a heat treatment and a drying treatment on the structure obtained in the process shown in FIG. 2B. Thereafter, etching is performed on this structure from above, and openings OP1 are formed in the cured resin layer 102 by removing portions of the cured resin layer 102. The openings OP1 may be formed using a procedure similar to the process shown in FIG. 1C.

In the process shown in FIG. 2D, a wiring layer 202 is formed on the resin layer 102, and also, vias 301 for connecting the wiring layers 201 and 202 are formed. This process can be realized by performing film forming processing using an electroless plating method or an electroplating method and patterning processing using a photoresist technology, similarly to the process shown in FIG. 1D. The structure obtained in this way is a flexible substrate SB1.

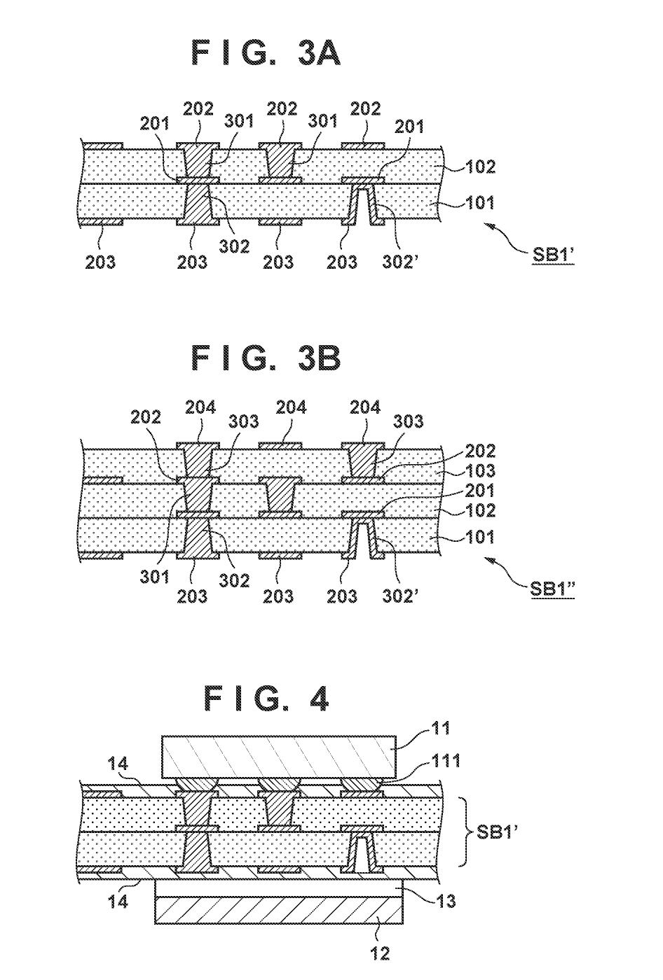

FIG. 3A shows a structure in which a wiring layer 203 and vias 302 and 302′ are further formed on a lower side of the flexible substrate SB1, and this structure is a flexible substrate SB1′. The wiring layer 203 and the vias 302 and 302′ can be formed using a procedure similar to the process described with reference FIG. 1E.

FIG. 3B shows a structure in which a third resin layer 103, a fourth wiring layer 204, and third vias 303 are further provided on an upper side of the flexible substrate SB1′, and this structure is a flexible substrate SB1″. The resin layer 103, the wiring layer 204, and the vias 303 may be formed using procedures similar to the processes shown in FIGS. 2B to 2D. Copper is used for the wiring layer 204 and vias 303, similarly to the wiring layer 202 and the vias 301.

As an example, first, a resin layer 103 in a B stage is formed on the upper side of the flexible substrate SB1 shown in FIG. 2D using a procedure similar to the process shown in FIG. 2B. Then, after the resin layer 103 is cured, the wiring layer 204 and the vias 303 are formed along with forming the wiring layer 203 and the vias 302 by performing etching, film forming processing, and patterning processing using procedures similar to the processes shown in FIGS. 2C and 2D.

Alternatively, as another example, first, the resin layer 103 in a B stage is formed on an upper side of the flexible substrate SB1′ shown in FIG. 3A using a procedure similar to the process shown in FIG. 2B. Then, after the resin layer 103 is cured, the wiring layer 204 and the vias 303 are formed by performing etching, film forming processing, and patterning processing, similarly to the processes shown in FIGS. 2C to 2D.

Note that it is possible to form five or more wiring layers by repeating the processes similar to the processes shown in FIGS. 2B to 2D. Alternatively, it is possible that the wiring layer 204 and the vias 303 are formed, but the wiring layer 203 and the vias 302 are not formed.

Predetermined electronic components are mounted, thereafter, on the flexible substrate SB1, SB1′, and/or SB1″ formed as described above, and the flexible substrate SB1, SB1′, and/or SB1″ are/is attached to an electronic device.

FIG. 4 is a schematic diagram illustrating an example of a mode of mounting an electronic component 11 on the flexible substrate SB1′. Here, a semiconductor apparatus or a semiconductor device in a BGA (Ball Grid Array) package, as the electronic component 11, is mounted on the flexible substrate SB1′ shown in FIG. 3A. When the electronic component 11 is mounted, the flexible substrate SB1′ is used in a state in which an upper surface and a lower surface thereof are coated by a solder resist layer 14.

The electronic component 11 includes a plurality of electrodes (solder balls) 111 that are arranged on a lower face of the package body. The mounting of the electronic component 11 on the flexible substrate SB1′ can be realized by electrically connecting the wiring layer 202 with the electrodes 111. In the present embodiment, a support member 12 is provided on the lower side of the flexible substrate SB1′ via an interposed layer 13 serving as an adhesion layer, for example. With this, the electronic component 11 can be appropriately fixed to the flexible substrate SB1′. When the flexible substrate SB1′ is attached to an electronic device, for example, the portion thereof on which the electronic component 11 is mounted is not bent, and as a result, the electronic component 11 is unlikely to detach from the flexible substrate SB1′.

It is preferable that the support member 12 is arranged so as to overlap the electronic component 11 when viewed in an orthogonal projection in a vertical direction or in plan view (when viewed in the vertical direction, which will be hereinafter simply referred to as “orthogonal projection” in the following description). It is further preferable that the support member 12 is arranged such that the outer edges of the support member 12 is outside the corresponding outer edges of the electronic component 11. A material having higher rigidity than the resin layers 101 and 102 is used as the support member 12, and a metal material, a resin material, or the like that is relatively difficult to be bent may be used. Note that when the support member 12 itself has an adhesive property or the like, for example, the interposed layer 13 may be omitted.

Also, as can be understood from FIGS. 4 and 3A, in the present embodiment, the vias 301 are formed as filled vias, and the wiring layer 202 is electrically connected to the wiring layer 201 with such vias 301. Therefore, the electronic component 11 described above can be electrically connected by directly mounting the electronic component 11 on the wiring layer 202 such that the electrodes 111 are on the corresponding vias 301. The electronic component 11 can be appropriately mounted on the flexible substrate SB1′ with a relatively simple configuration.

The filled vias 301 and 302 and the conformal via 302′ may be selectively provided depending on whether or not the part in which the via is formed is a part of the flexible substrate SB1′ that is to be bent when used. For example, the conformal via 302′ may be provided in a part of the flexible substrate SB1′ that is to be bent when used, and the filled vias 301 and 302 may be provided in other parts. From this viewpoint, it can also be said that the electronic component 11 is located/mounted at a position so as to overlap the filled vias 301 and the wiring layer 201 in an orthogonal projection.

As described above, according to the present embodiment, the wiring layer 201 and the resin layer 102 are in direct contact with each other, and as a result of the layers being appropriately brought into close contact, the exfoliation thereof (including creases and crinkles) can be prevented/suppressed from occurring. Also, accordingly, the fixing of the resin layer 101 and the resin layer 102 can be appropriately realized.

In the present embodiment, the resin layer 102 is in direct contact with an upper face and side faces of each wiring pattern 201a in the wiring layer 201 in a cross-sectional view, and with this, they are strongly fixed, and the above-mentioned exfoliation or the like are appropriately prevented. In such a structure, the resin layer 102 has a lower face having an uneven shape. The fixing of the wiring layer 201 and the resin layer 102 can be realized by the resin layer 102 being in direct contact with at least one of the upper face and the side faces (in many cases, the upper face, and a portion/all of the side faces in addition) of each wiring pattern 201a of the wiring layer 201. The larger the contact area, the better.

In order to more appropriately prevent the above-mentioned exfoliation, the resin layer 102 may be integrally formed on the resin layer 101 such that portions between the adjacent patterns 201a in the wiring layer 201 are filled. Here, if the height of the wiring layer 201 is increased, and the distance between the adjacent patterns 201a is reduced, the wiring layer 201 and the resin layer 102 are fixed more strongly. The parameters such as height and distance may be determined based on constituent materials of the flexible substrate SB1 and the like such as the material of the resin layer 102 (diameters or the like of constituent particles), for example. For example, in the present embodiment, when the height of the wiring layer 201 is denoted as H, and the minimum distance between the adjacent patterns 201a is denoted as L, it is preferable that these parameters satisfy H≥5 μm and L≤50 μm. It is further preferable that the height H satisfies H≥7 μm, and more preferably H≥9 μm. Also, it is further preferable that the distance L satisfies L≤40 μm, and more preferably L≤30 μm.

In the present embodiment, the wiring layers 201 and 203 are formed to have a height of about 9 μm and the wiring layer 202 is formed to have a height of about 10 μm on the resin layer 101 having a thickness of about 25 μm and the resin layer 102 having a thickness of about 20 μm. The vias 301 and the like are formed to have a diameter of about 30 to 50 μm, and the width of each pattern and the distance between adjacent patterns of the wiring layers 201 to 203 (so-called line and space) are about 25 μm. Note that, at connection portions with the vias 301, the width of each pattern of the wiring layers 201 to 203 is about 100 μm.

Also, in the present embodiment, polyimide is used in the resin layers 101 and 102, but another resin may be used. Various types of modified resin such as a thermoplastic resin, a thermosetting resin, and an ultraviolet curing resin can be used. Typically, polyimide-based resin (such as polyimide, polyetherimide, and polyamidimide) is preferably used in order to improve elasticity and thermal resistance, but another types of resin such as a polyamide-based resin and a polyester-based resin may be used. Here, the resin layers 101 and 102 may be formed with the same material in order to prevent the aforementioned exfoliation or the like by reducing the difference in the coefficient of thermal expansion therebetween.

In the present embodiment, the resin layer 101 and the resin layer 102 are in direct contact with each other, and with this, the resin layers 101 and 102 are appropriately in close contact with each other without the adhesion layer 901 being interposed therebetween. As described with reference to FIG. 2B and the like, the resin layer 102 is formed by curing a resin material in a B stage, that is, formed by curing a resin material that has been applied in a semi-cured state. Therefore, the resin layer 101 and the resin layer 102 are strongly fixed to each other. In this case, an epoxy-based resin, a urethane-based resin, a silicone-based resin, or the like may be used as the resin layer 102. Also, as a result of the resin layer 101 and the resin layer 102 being in direct contact with each other, and the adhesion layer 901 being not used, the thickness of the flexible substrate SB1 or the like can be reduced, and the flexible substrate SB1 or the like can have appropriate flexibility.

Here, a description has been given focusing on the fixing between the wiring layer 201 and the resin layer 102. In the case of the flexible substrate SB1″ shown in FIG. 3B, the same idea can be applied to the fixing between the wiring layer 204 and the resin layer 103. This can similarly be applied to a case where the number of wiring layers is five or more.

Furthermore, with regard to the manufacturing method, in the process shown in FIG. 2B, when the resin layer 102 in a B stage is bonded to the resin layer 101 through thermocompression bonding, a pressing surface of a thermocompression bonding apparatus that performs the thermocompression bonding may have an uneven shape. With this, the resin layer 102 can be formed such that the upper surface thereof has an uneven shape, and therefore, the exfoliation of the wiring layer 202 that is formed in a later process from the resin layer 102 can be appropriately suppressed. Also, as a result of providing projections on a pressing surface of a thermocompression bonding apparatus, openings for vias 301 that are formed in a later process can be formed in the resin layer 102 along with performing the thermocompression bonding. That is, the process shown in FIG. 2C can be omitted.

The resin layer 101 prepared for use in the process shown in FIG. 2A may be a resin layer on which a metal film such as a copper film has been formed, in advance, via a predetermined adhesion layer. However, this adhesion layer is used when the metal film and the resin layer 101 are adhered to each other, and in many cases, this adhesion layer has been already modified and lost its adhesive force at some point in time during the process shown in FIG. 2B. According to the present embodiment, even in a case where such a resin layer 101 is used, the wiring layer 201 and the resin layer 102 can be fixed to each other, and accordingly, fixing between the resin layer 101 and the resin layer 102 can be appropriately realized.

The flexible substrate SB1 or the like according to the present embodiment is used as a connection portion in which an electronic component 11 can be mounted, or as a connection portion for connecting two or more electronic components 11, and can be preferably applied to various electronic devices such as a printer and a scanner. A BGA package is shown in FIG. 4 as an example of the electronic component 11, but the electronic component 11 is not limited to this example. For example, another semiconductor package such as QFP (Quad Flat Package) may be mounted on the flexible substrate SB1 or the like, or may be connected to the flexible substrate SB1 or the like or a rigid substrate. The electronic component 11 is, through the electrodes 111, directly mounted on the wiring layer 202 that is connected to the wiring layer 201 by the filled vias 301, and is electrically connected to the wiring layer 202. Accordingly, the electronic component 11 can be appropriately mounted with a relatively simple configuration.

### Second Embodiment

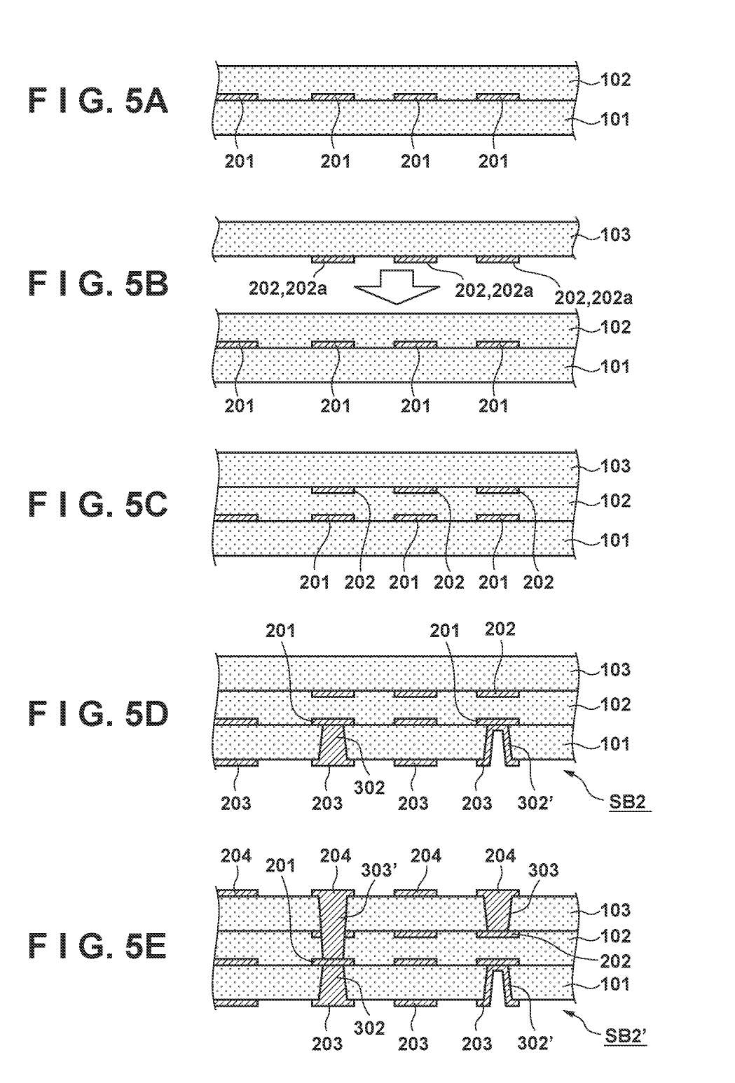

The second embodiment differs from the first embodiment in that a wiring layer 202 is embedded in a resin layer 102. The same effects as those of the first embodiment can also be achieved in the present embodiment. FIGS. 5A to 5E show modes of respective processes in the manufacturing method according to the present embodiment.

First, in the process shown in FIG. 5A, a resin layer 102 in a B stage is formed on a resin layer 101 so as to cover the wiring layer 201 with procedures similar to those shown in FIGS. 2A and 2B. Thereafter, in the process shown in FIG. 5B, a resin layer 103 in which a wiring layer 202 is arranged on a lower face thereof is bonded to this structure from above. In this process, since the resin layer 102 is in a B stage (deformable), the resin layers 102 and 103 are brought into close contact with each other such that portions between adjacent patterns 202a of the wiring layer 202 on the lower face of the resin layer 103 are filled by the resin layer 102. Accordingly, the resin layer 102 is in direct contact with side faces of the wiring patterns 202a of the wiring layer 202, and the resin layer 102 has an upper surface having an uneven shape. To put it differently from a viewpoint of the wiring layer 202, the wiring layer 202 is located on the resin layer 102 such that the wiring layer 202 is embedded in the resin layer 102. This process may be performed using a known application apparatus.

In the process shown in FIG. 5C, the resin layer 102 in a B stage is cured (so as to be in a C stage) by performing a heat treatment and a drying treatment on a structure obtained in the process shown in FIG. 5B.

In the process shown in FIG. 5D, a wiring layer 203 and vias 302 and 302′ are formed on a lower side of the structure obtained in the process shown in FIG. 5C. This wiring layer 203 and these vias 302 and 302′ can be formed using procedures similar to those used in the above-described first embodiment or the reference example. The structure obtained in this way is a flexible substrate SB2.

Also, as shown in FIG. 5E, a wiring layer 204 and vias 303 and 303′ may be formed, in addition, on an upper side of the flexible substrate SB2. This structure is a flexible substrate SB2′. Also, five or more wiring layers may be provided using similar procedures.

The wiring layer 204 and the via 303, of the wiring layer 204 and the vias 303 and 303′, are the same as those in the first embodiment, and therefore, the description thereof will be omitted (refer to FIG. 3B). On the other hand, the via 303′ is provided so as to connect the wiring layers 201 and 204. In the present embodiment, since the resin layer 102 is in a B stage in the process shown in FIG. 5B, a connection portion (or any member for connecting the wiring layers 201 and 202) corresponding to the via 301 is not formed in this resin layer 102, and the via 303′ is formed in the process shown in FIG. 5E. With this, electrical connection similar to the first embodiment can be realized.

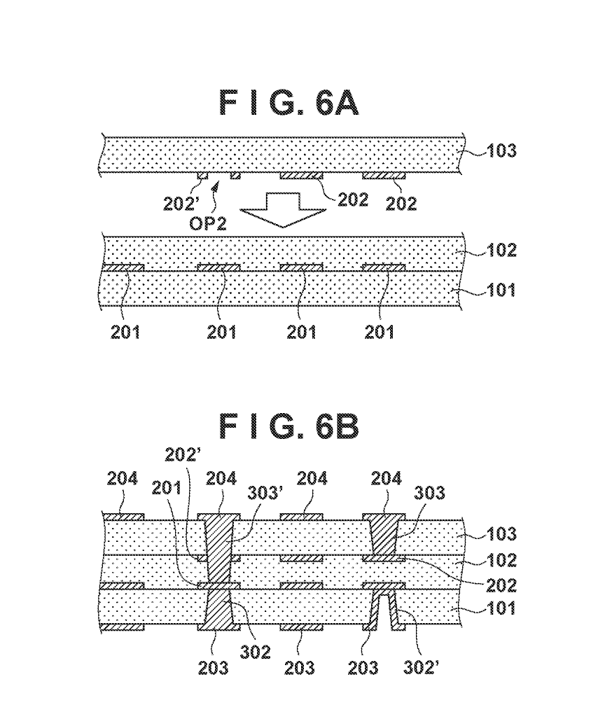

Note that, in the present embodiment, an opening is provided in the wiring layer 202 through which the via 303′ will pass by performing etching using a laser in the process shown in FIG. 5E, and thereafter, the via 303′ is formed so as to pass through the opening. In another embodiment, this wiring layer 202 may be provided in a state in which an opening has been formed in advance (at some point in time during the process shown in FIG. 5B). For example, a resin layer 103, in which a wiring layer 202′ having an opening OP2 is arranged on a lower face thereof, is bonded to a structure obtained by the process shown in FIG. 5A from above, as shown in FIG. 6A. As a result of thereafter forming the wiring layers 203 and 204 and the vias 302, 303, and 303′ using procedures similar to those shown in FIGS. 5C to 5E, a wiring structure similar to the flexible substrate SB2′ can be relatively easily formed, as shown in FIG. 6B.

According to the present embodiment, similarly to the fixing between the wiring layer 201 and the resin layer 102, the wiring layer 202 and the resin layer 102 can be strongly fixed to each other. Therefore, according to the present embodiment, the reliability of the flexible substrate SB2 or the like can be improved.

### Others

Some preferable embodiments have been illustrated above, but the present invention is not limited to these examples, portions thereof may be modified without departing from the spirit of the invention. Also, the individual terms recited herein are merely used for the purpose of describing the present invention, and the invention is not intended to be limited to a strict interpretation of the meaning of those terms, and can also include equivalents thereof. For example, in this specification, the wiring layers 201 and the like refer to layers in which wiring patterns are formed and that are arranged above/below the resin layers 101 and the like or therebetween, but may be expressed as conductive layers, metal layers, or the like. Similarly, the vias 301 and the like refer to portions for connecting two wiring layers that overlap in the vertical direction, but may be expressed as plugs or the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2017-232719, filed Dec. 4, 2017, and No. 2018-223936, filed Nov. 29, 2018, which are hereby incorporated by reference herein in their entirety.

What is claimed is:

1. A flexible substrate comprising:
a first resin layer;
a first wiring layer that is arranged on the first resin layer;
a second resin layer that is arranged on the first resin layer so as to cover the first wiring layer; and
a second wiring layer that is arranged on the second resin layer,
wherein the first wiring layer and the second wiring layer are connected to each other with a filled via, and the first wiring layer and the second resin layer are in direct contact with each other.

2. The flexible substrate according to claim 1, wherein the first wiring layer includes a wiring pattern, and the second resin layer is in direct contact with at least one of an upper face and a side face of the wiring pattern.

3. The flexible substrate according to claim 2, wherein the first wiring layer includes a plurality of the wiring patterns in a cross-sectional view, and when a height of the first wiring layer is denoted as H and a minimum distance between wiring patterns that are adjacent to each other in the first wiring layer is denoted as L, H and L satisfy H≥5 μm and L≤50 μm.

4. The flexible substrate according to claim 1, wherein a lower face of the second resin layer has an uneven shape.

5. The flexible substrate according to claim 1, further comprising a first via, as the filled via, that is provided so as to pass through the second resin layer such that the first wiring layer and the second wiring layer are electrically connected.

6. The flexible substrate according to claim 1, further comprising a third wiring layer that is arranged under the first resin layer.

7. The flexible substrate according to claim 6, further comprising a second via that is provided so as to pass through the first resin layer such that the first wiring layer and the third wiring layer are electrically connected.

8. The flexible substrate according to claim 1, wherein the first resin layer and the second resin layer are in direct contact with each other.

9. The flexible substrate according to claim 1, wherein the first resin layer and the second resin layer are each an integrally formed thermoplastic resin.

10. The flexible substrate according to claim 1, wherein the first resin layer and the second resin layer are each an integrally formed thermosetting resin.

11. The flexible substrate according to claim 1, wherein the first resin layer and the second resin layer are made of a same material.

12. The flexible substrate according to claim 1, wherein the first resin layer and the second resin layer are each a polyimide layer.

13. The flexible substrate according to claim 1, wherein the second resin layer is formed by curing a resin material in a B stage.

14. The flexible substrate according to claim 1, further comprising an electronic component that is mounted on the second wiring layer.

15. The flexible substrate according to claim 14, further comprising a support member having higher rigidity than the first resin layer and the second resin layer,
wherein the support member is arranged under the first resin layer so as to overlap the electronic component in an orthogonal projection in a vertical direction.

16. The flexible substrate according to claim 14, wherein the electronic component is placed so as to overlap the filled via in an orthogonal projection in the vertical direction, and is directly connected to the second wiring layer.

17. The flexible substrate according to claim 1, wherein the second wiring layer includes a wiring pattern, and the second resin layer is in direct contact with a side face of the wiring pattern.

18. A flexible substrate comprising:
a first resin layer;
a first wiring layer that is arranged on the first resin layer;
a second resin layer that is arranged on the first resin layer so as to cover the first wiring layer; and
a third wiring layer that is arranged under the first resin layer,
wherein the first wiring layer and the third wiring layer are connected to each other with a filled via, and the first wiring layer and the second resin layer are in direct contact with each other.

19. An electronic device comprising the flexible substrate according to claim 1.

20. An electronic device comprising the flexible substrate according to claim 18.
